(19) United States
(12) Patent Application Publication
(10) Pub. No.: US 2012/0106036 A1
(43) Pub. Date: May 3, 2012

(54) BUILT-IN TYPE ANTENNA DISPLAYER

(76) Inventor: PEN-JUNG KAO, TAIPEI (TW)

(21) Appl. No.: 12/966,125

(22) Filed: Dec. 13, 2010

(30) Foreign Application Priority Data
Nov. 2, 2010 (TW) 099137633

(51) Int. Cl. H05K 7/00

(52) U.S. Cl. 361/679.01

(57) ABSTRACT

A built-in type antenna displayer, formed by at least an antenna integrally on a metal frame, and said metal frame is fixed onto an outer edge of a display panel, on said outer edge of said display panel is provided with an installation surface. Said metal frame is provided with a first sidewall, and a second sidewall connected vertically to said first sidewall, so as to form an L-shape structure. On said first sidewall is formed a signal feed-in terminal and a ground terminal, and that are both located on said installation surface. On said second sidewall is provided with a resonance radiator, that is connected vertically to said installation surface, such that said resonance radiator is connected vertically to said signal feed-in terminal to form a non-coplanar structure having a WLAN triple band antenna.

### BACKGROUND OF THE INVENTION

1. Field of the Invention

The present invention relates to a displayer, and in particular to a non-coplanar type Wireless Local Area Network (WLAN) triple band antenna structure formed integrally on a metal frame of a displayer.

2. The Prior Arts

Along with the progress and development of computer technology, notebook computer is now very popular and widely utilized, and it has become an indispensable part in the work and life of people of the modern age. Therefore, the functions provided by the notebook computer and its convenience in usage are essential to the efficiency of carrying on our daily life. In addition, with the advent of the age of wireless network communications, notebook computer is now equipped with antenna in achieving wireless communications. In the design and arrangement of an antenna, it must fulfill all the users' requirements of light-weight, thin-profile, and compact-size of a notebook computer at the same time, so the design and arrangement of antenna is a very important task.

In the prior art, in order to achieve wireless communications, an outside antenna is put directly on top of a displayer of a notebook computer, thus making it capable of transmitting/receiving radio frequency (RF) signals efficiently. However, the cost of this kind of outside antenna is rather high, hereby raising the price of the notebook computer having wireless communication capabilities. Moreover, since this type of outside antenna is provided on a displayer in a protrusion manner, and except for the housing of the antenna, it lacks outside cover and protection for the main body of antenna, therefore, after long period of usage, this type of outside antenna is liable to be damaged due to improper handling of the user, thus making the notebook computer not being able to realize wireless data communications.

In order to avoid high cost and insufficient protection of the outside antenna, an embedded antenna type notebook computer is proposed. Refer to FIG. 1 for a perspective view of an embedded antenna type notebook computer of the prior art. As shown in FIG. 1, the notebook computer 10 comprises a main body 12, and a displayer 14. For the displayer 14, only a portion of its components are shown after its outside cover is removed. In the displayer 14 is provided with a metal frame 16 and at least an antenna 18, wherein, the metal frame 16 is used to support the displayer 14, and the antenna 18 extends from the outer edge of the metal frame 16, in achieving signal transmission/receiving wirelessly. However, in order to achieve the objective of light-weight, thin-profile, and compact-size of a notebook computer 10, the size of displayer 14 must be reduced, hereby diminishing a space 20 between metal frame 16 and outer perimeter of the displayer 14. Usually, the space 20 is used for placing cables or components of digital camera, and when this space 20 is reduced, that would cause the congestion of components (including antenna 18) contained therein, or even some of the components have to be removed. Moreover, in case that coaxial cables are placed on the non-metal surface on the back of a displayer 14, then due to diameter of the coaxial cable and height of its welding point, the coaxial cables may be broken for being pressed by outside force during assembly, or the displayer may be broken for being pressed by the coaxial cables. In order to solve this problem, the overall thickness of the display panel and the plastic cover plate has to be increased.

In addition, refer to FIG. 2 form schematic diagram of a displayer frame of an antenna structure of the prior art. As shown in FIG. 2, the metal cover plate 22 is connected to ground, and on the folded edge (sidewall) 24 of the metal cover plate 22 is formed a coplanar inverse F-shape antenna 26 having signal feed-in point and resonance radiator. However, in this structure, thicker space is required to avoid interference of components. Yet under the demand of thin-profile of notebook computer, in case the display panel of thickness less than 4 mm is utilized, then a wideband WLAN triple band antenna can not be realized due to insufficient thickness.

Therefore, at present, the design and structure of the antenna displayer are not quite satisfactory, and it has much room for further improvement.

### SUMMARY OF THE INVENTION

In view of the problems and shortcomings of the prior art, the present invention provides a built-in type antenna displayer, so as to overcome the problem and shortcomings of the prior art.

A major objective of the present invention is to provide a built-in type antenna displayer, that is formed on a metal frame of a displayer of a non-coplanar antenna, so as to solve the problem of the prior art of the additional installation cost for the antenna and the additional space occupied by the width, length and height of the antenna.

Another objective of the present invention is to provide a built-in type antenna displayer, that could avoid placing the signal feed-in point of the antenna at the front side or back side of the display panel, since that would have the shortcomings of increasing the thickness of the notebook computer, and also causing the breaking of the welding points of the coaxial cable for being pressed by outside force, or the breaking of the display panel for being pressed by the coaxial cable.

A yet another objective of the present invention is to provide a built-in type antenna displayer, such that a wireless local area network (WLAN) triple band wideband antenna is formed on a metal frame, so as to avoid the problem of resonance frequency deviation of an antenna of the prior art, as caused by the size difference of metal frame and metal bracket, or the difference of dielectric coefficients of a display panel and a plastic cover plate.

To achieve the above-mentioned objective, the present invention provides a built-in type antenna displayer, comprising a display panel, having an installation portion on its outer edge; a metal frame fixed on the outer side of the display panel, the metal frame is provided with a first sidewall, and a second sidewall connected vertically to the first sidewall, the first sidewall is disposed parallel to the installation portion, and the second sidewall and the installation portion is connected vertically; a pair of symmetric first metal bracket and a second metal bracket are disposed respectively on two ends of the metal frame; and at least a first antenna, formed integrally on the metal frame, and on the first sidewall is provided with a first signal terminal having a first signal feed-in point, and a first ground terminal having a first ground point, on the second sidewall is provided with a first resonance radiator, and the first resonance radiator is connected vertically to the first signal feed-in point, so as to form a non-coplanar structure, one end of the first ground terminal is connected to a first metal bracket, with its other end extended and connected to a second metal bracket.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a perspective view of a notebook computer according to the prior art;

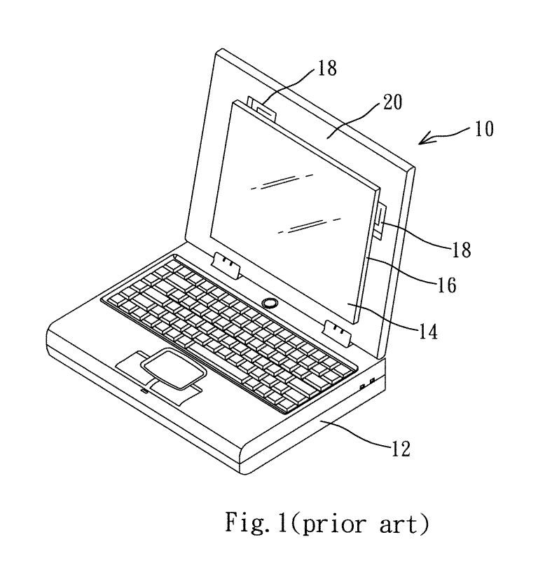

FIG. 2 is a schematic diagram of a displayer frame of an antenna structure according to the prior art;

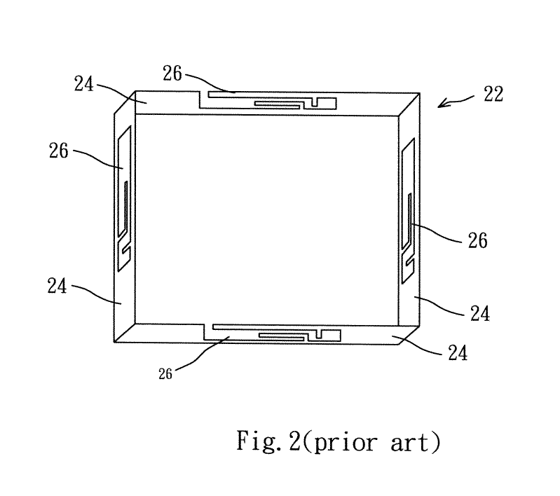

FIG. 3 is a perspective view of a built-in type antenna displayer according to the present invention;

FIG. 4 is a schematic diagram for a structure of a built-in type antenna displayer according to the present invention;

FIG. 5 is a schematic diagram showing a structure of a bend-shape resonance radiator according to the present invention;

FIG. 6 is a diagram of radiation distribution of an antenna operating at 2.4 G Hertz according to the present invention;

FIG. 7 is a diagram of radiation distribution of an antenna operating at, 5.2 G Hertz according to the present invention;

FIG. 8 is a diagram of radiation distribution of an antenna operating at 5.8 G Hertz according to the present invention;

FIG. 9 is a schematic diagram of structure of antenna displayer having assembled plastic cover plate and plastic surface frame according to the present invention; and

FIG. 10 is a schematic diagram showing a pair of symmetric antennas formed integrally on a metal frame according to the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

In view of the present trend of light-weight, thin-profile, and compact-size of the notebook computer, and in consideration of resonance frequency deviation of the antenna, as caused by the size differences of metal frame and metal bracket, or the difference of dielectric coefficients of display panel and the plastic cover plate, the present invention adopts a special design of a wide bandwidth antenna, such that it can not only be adapted to use in a thin-profile displayer, but it can also avoid the adverse influence of different ways of fixing metal brackets.

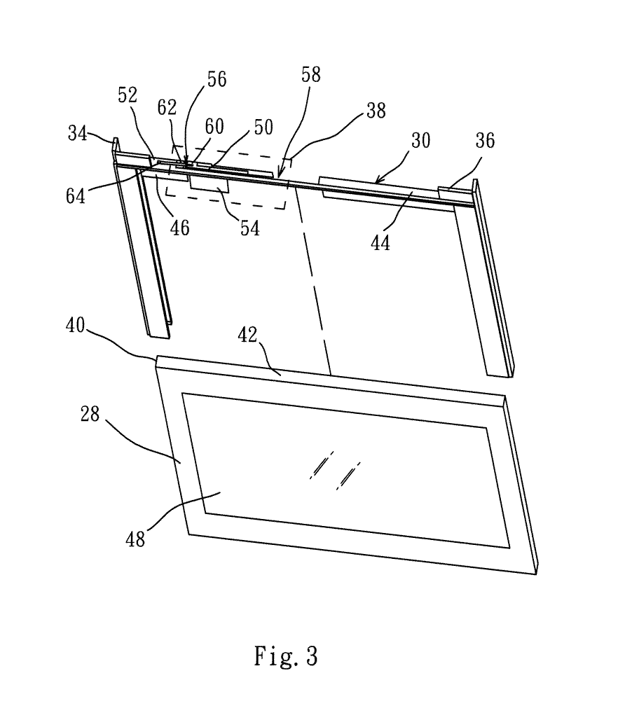

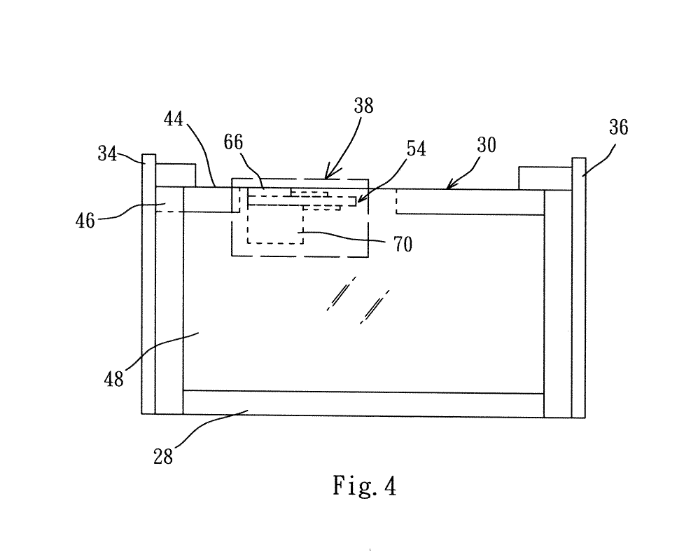

Refer to FIGS. 3 and 4 at the same time for an exploded view and a schematic diagram respectively of the built-in type antenna displayer according to the present invention. As shown in FIGS. 3 and 4, a displayer of the present invention includes a display panel 28, a metal frame 30, a pair of symmetric first metal bracket 34 and a second metal bracket 36, and at least a first antenna 38. The outer edge 40 of the displayer panel 28 is provided with an installation surface 42, wherein, the thickness of the display panel 28 is preferably less than 5 mm. The metal frame 30 is fixedly installed on the outer edge 40 of the display panel 28, the first metal bracket 34 and the second metal bracket 36 are disposed on two ends of the metal frame 30 respectively. Wherein, the metal frame 30 is provided with a first sidewall 44, and a second sidewall 46 connected vertically to the first sidewall 44, so as to form an L-shape structure. The first sidewall 44 is located on the installation surface 42, and is vertical to a display screen 48 of the display panel 28. The second sidewall 46 is connected vertically to the installation surface 42, and is parallel to the display screen 48 or backside of the display panel 28. Herein, the structure of the second sidewall 46 parallel to the backside of the display panel 28 is taken as an example for explanation.

In the present invention, the first antenna 38 can be one or more antenna formed integrally on the metal frame 30. Herein, a first antenna 38 is taken as an example for explanation. The first antenna 38 is disposed on the first sidewall 44, and is provided with a first signal feed-in terminal 50 and a first ground terminal 52. A first resonance radiator 54 is provided on the second sidewall 46, and the first resonance radiator 54 and the first signal feed-in terminal 50 are connected vertically, on as to form a non co-planar structure. Wherein, one end of the first ground terminal 52 is connected to a first metal bracket 34, with its other end is extended and connected to the second metal bracket 36. The metal frame 30 and the first metal bracket 34 are utilized as the ground plane of the first antenna 38.

A first open slot 56 is provided between the first signal feed-in terminal 50 and a first ground terminal 52, and a second open slot 58 is provided between the first signal feed-in terminal 50 and the first resonance radiator 54, wherein, the first signal feed-in terminal 50 can be of a stepwise shape, and a first signal feed-in point 60 is disposed thereon. A first ground terminal 52 is provided with a first ground point 62, which can be connected to first signal feed-in point 60 through a signal wire of a coaxial cable 64, and the ground wire of the coaxial cable 64 is connected to the first ground point 62. Since first signal feed-in terminal 50 and the first ground terminal 52 are located on the first sidewall 44 of the metal frame 30, therefore, coaxial cable 64 can avoid the shortcomings that, the signal feed-in point of the antenna is provided at the front side or back side of the display panel 28, since that would increase the overall thickness of the display panel and the plastic cover plate, hereby resulting in the breaking of the welding points of the coaxial cable 64 for being pressed by outside force, or the breaking of the display panel 28 for being pressed by the coaxial cable 64.

Then, refer to FIG. 4 for a schematic diagram of a structure of a built-in type antenna displayer according to the present invention. As shown in FIG. 4, the first antenna 38 is a WLAN triple band antenna, a first resonance radiator 54 of the first antenna 38 includes a first radiation portion 66, having a first frequency band containing the first resonance frequency, such as that as specified in 802.11g communication protocol of WLAN Specification, and is connected to the first signal feed-in terminal 50; and a second radiation portion 70 having a second and a third frequency bands containing a second and a third resonance frequencies, such as those as specified in 802.11a communication protocol of WLAN Specification, and the second radiation portion 70 is connected to the first radiation portion 66. Wherein, the structures of the first radiation portion 66 and the second radiation portion 70 are designed into shapes of different lengths and widths, that can be adjusted to operate at different resonance frequencies and bandwidths.

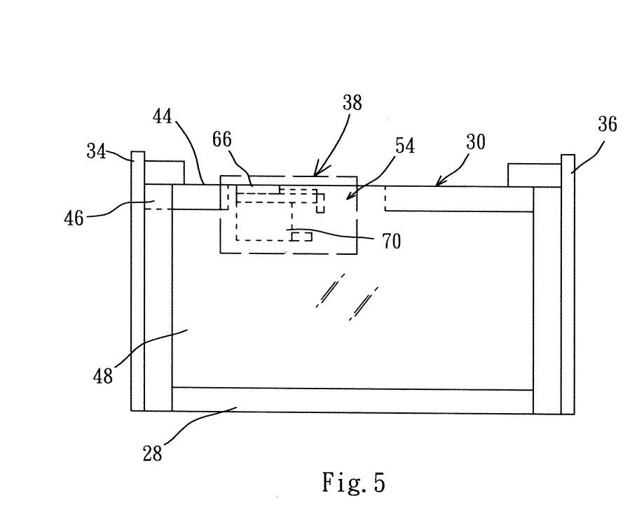

Subsequently, refer to FIG. 5 for a schematic diagram showing a structure of a bend-shape resonance radiator, wherein, the first radiation portion 66 and the second radiation portion 70 can be designed into a bend-shape or a polygon, such that not only the travel route of the current signal is longer, but the resonance frequency or the bandwidth can also be changed or adjusted. Since the first resonance radiator 54 is located on the second sidewall 46 of the metal frame 30, as such, there are enough thickness and space for designing a WLAN triple band antenna of wide bandwidth.

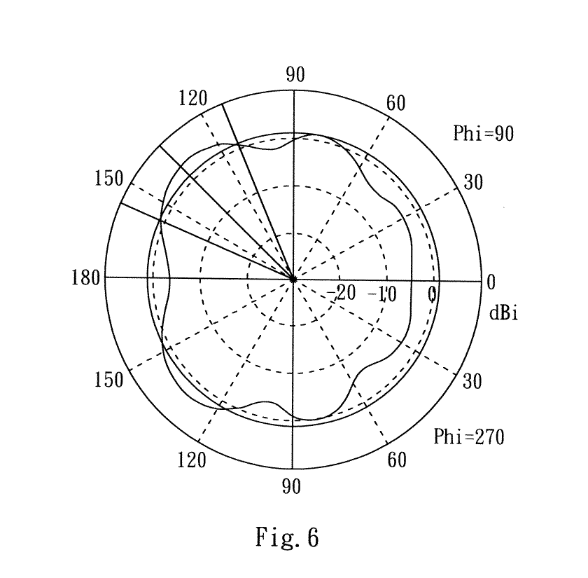

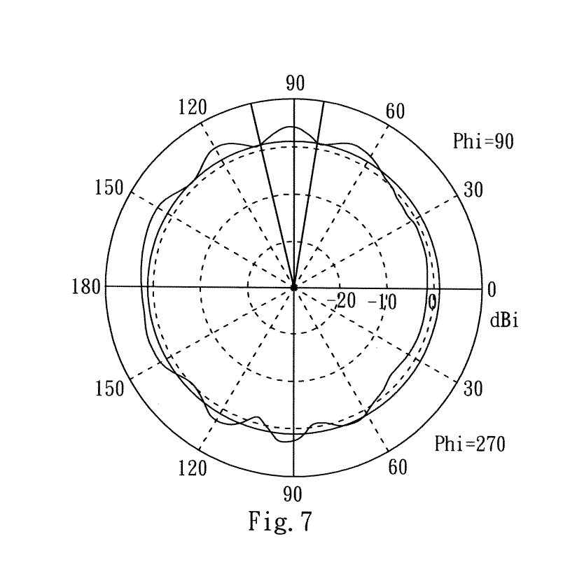

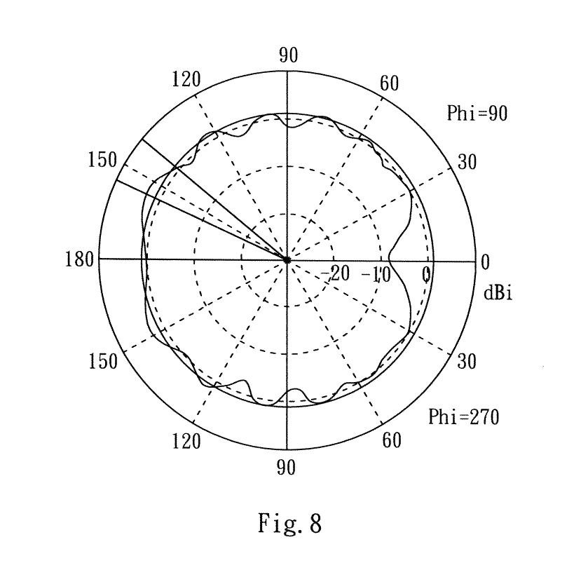

According to the structure design mentioned above, the range of preferred bandwidths of the first frequency band, the second frequency band, and the third frequency band can be designed to operate in the resonance frequency bands of 2.4 G-2.5 G Hertz, 5.15 G-5.35 G Hertz, and 5.35 G-5.9 G Hertz, however, the present invention is not limited to these ranges of bandwidth, such that range of resonance frequency can be of wider bandwidth by changing the structure designs of the first radiation portion 66 and the second radiation portion 70 as based on actual requirements. Refer to FIGS. 6, 7, and 8 respectively at the same time for diagrams of radiation distribution of antenna operating at 2.4 G Hertz, 5.2 G Hertz, and 5.8 G Hertz. Since the first resonance radiator 54 is connected vertically to the signal feed-in point 60, such that the signal feed-in point 60 is used for input and output of current signal, and the first ground point 62, the first ground terminal 52, and metal frame 30 are used as ground. In order to regulate impedance of the input current, the area or shape of the first open slot 56 can be varied, so that the route length of current between the first signal feed-in terminal 50 and the first ground terminal 52 is increased or reduced, so as to achieve varying bandwidth of the transmission/receiving frequency of the antenna.

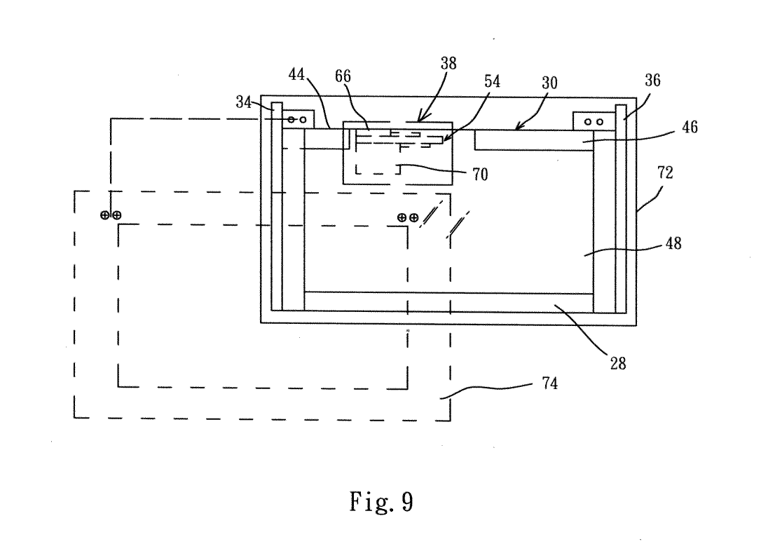

Then, refer to FIG. 9 for a schematic diagram of structure of antenna displayer having assembled plastic cover plate and plastic surface frame according to the present invention. As shown in FIG. 9, the displayer further includes a plastic cover plate 72 and a plastic surface frame 74, the plastic cover plate 72 is installed on the backside of the display panel 28, and a lock-and-fix piece is used to lock and fix the first metal bracket 34 and the second metal bracket 36 onto the plastic cover plate 72, so that the plastic surface frame 74 is installed correspondingly on the plastic cover plate 72, and covers only the first metal bracket 34, the second metal bracket 36, and the metal frame 30 forming a coplanar structure with the first antenna 38, on as to expose the display screen 48 of the display panel 28. Since in the present invention, the first resonance radiator 54 of WLAN low frequency section 2.4 G-2.5 G Hertz is designed on the first radiation portion 66 utilizing ¼ wavelength, and the first resonance radiators 54 of WL/\N high frequency sections 5.15 G-5.35 G Hertz and 5.35 G-5.85 G Hertz are designed on the second radiation portion 70 utilizing ¼ wavelength, hereby realizing a non co-planar structure WLAN triple band antenna, with its bandwidth design taking into considerations of ranges of the difference variations of the attached plastic material and the metal bracket, such that it can meet the specifications as specified by the Industry and achieve standardization. As such, not only the structure design of the first resonance radiator 54 is improved in providing different WLAN antenna designs, but the cost and time spent on material, molding, research and development can also be reduced. Besides, it can solve the problem of resonance frequency deviation of the prior art incurred due to the differences of dielectric coefficients of metal bracket, display panel 28, and plastic cover plate 72.

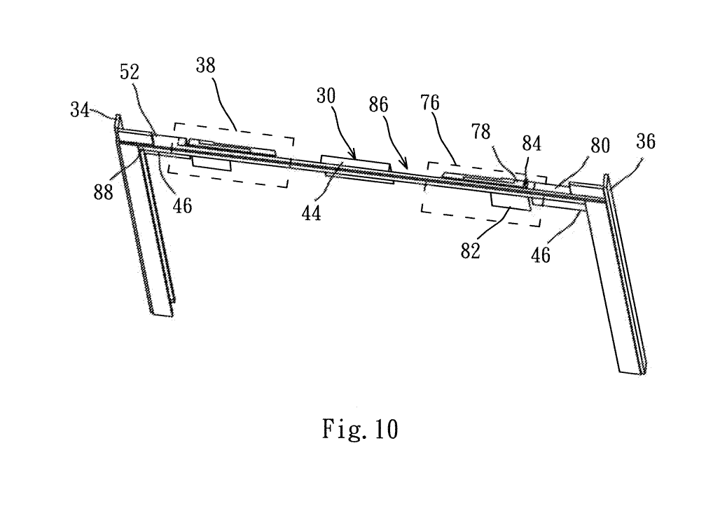

Finally, refer to FIG. 10 for a schematic diagram showing a pair of symmetric antennas formed integrally on a metal frame according to the present invention. As shown in FIG. 10, the difference between FIG. 10 and FIG. 3 is that, in addition to a first antenna 38 formed on a metal frame 30, at least a second antenna 76 is provided, and that is formed integrally with the first antenna 38 on two ends of the metal frame 30 respectively, and the second antenna 76 is adjacent to the second metal bracket 36. On the first sidewall 44 is provided with a second signal feed-in terminal 78 and a second ground terminal 80; and on the second sidewall 46 is provided with a second resonance radiator 82, and that is connected vertically to the second signal feed-in terminal 78, so as to form a non-coplanar structure. One end of the second ground terminal 80 is connected to the second metal bracket 36, with its other end extended and connected to the first ground terminal 52 of the first antenna 38. Wherein, a third open slot 84 is provided between the second signal (eed-in terminal 78 and the second ground terminal 80, and a fourth open slot 86 is provided between the second signal feed-in terminal 78 and the second resonance radiator 82. The functions and operations of the second antenna 76 are the same as those of the first antenna 38, and it will not be repeated here for brevity.

Herein, it has to be mentioned specifically that, the second antenna 76 and the first antenna 38 are disposed in corresponding positions, and formed integrally on two ends of the metal frame 30, thus achieving its major objective that, relative to a single antenna, the application of two antennas can reduce signal isolation of displayer in certain directions, and provide better space versatility for the wireless communication system, or it can be used to achieve multiple-input-multiple-output (MIMO) effect, or it may permit the utilization of Blue Tooth communications having the same frequency bandwidth.

In addition, the metal frame 30 may include a third sidewall 88, connected vertically to a first sidewall 44, and is parallel to the second sidewall 46, and it is also connected to the first ground terminal 52 and the second ground terminal 80. Wherein, the width of the portion of the third sidewall 88 close to the first resonance radiator 54 and the second resonance radiator 82 must be smaller than that of the second sidewall 46, and also its width must not be greater than the width of the first resonance radiator 54 and the second resonance radiator 82, so as not to affect the resonance radiation of the antenna.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A built-in type antenna displayer, comprising:
a display panel, having an installation surface on its outer edge;
a metal frame, fixed on said outer edge of said display panel, said metal frame is provided with a first sidewall, and a second sidewall connected vertically to said first sidewall, said first sidewall is disposed on said installation surface, and said second sidewall and said installation surface are connected vertically; and
at least a first antenna, formed integrally on said metal frame, a first signal feed-in terminal and a first ground terminal are disposed on said first sidewall, a first resonance radiator is provided on said second sidewall, and said first resonance radiator is connected vertically to said first signal feed-in terminal, so as to form a non-coplanar structure.

2. The built-in type antenna displayer as claimed in claim 1, wherein a first open slot is provided between said first signal feed-in terminal and said first ground terminal, and a second open slot is provided between said first signal feed-in terminal and said first resonance radiator.

3. The built-in type antenna displayer as claimed in claim 1, wherein said metal frame further includes a third sidewall, connected vertically to said first sidewall and is parallel to said second sidewall, width of said third sidewall is smaller than width of said second wall, and is connected to said first ground terminal.

4. The built-in type antenna displayer as claimed in claim 1, wherein said first antenna comprises a triple band antenna, said first resonance radiator of said first antenna includes:
a first radiation portion, having a first frequency band containing a first resonance frequency, and is connected to said signal feed-in terminal; and
a second radiation portion, having a second frequency band containing a second resonance frequency, and a third frequency band containing a third resonance frequency, and said second radiation portion is connected to said first radiation portion.

5. The built-in type antenna displayer as claimed in claim 4, wherein structures of said first radiation portion and said second radiation portion are designed into shapes of different lengths and widths, and are operated at different resonance frequencies respectively.

6. The built-in type antenna displayer as claimed in claim 4, wherein said structures of said first radiation portion and said second radiation portion are designed into a bend-shape or a polygon.

7. The built-in type antenna displayer as claimed in claim 1, wherein a first metal bracket and a second metal bracket are provided respectively on two ends of said metal frame, such that one end of said first ground terminal is connected to said first metal bracket, with its other end extended and connected to said second metal bracket.

8. The built-in type antenna displayer as claimed in claim 7, further comprising: at least a second antenna, formed with said first antenna integrally on two ends of said metal frame, said second antenna is close to said second metal bracket, on said first sidewall is provided with a second signal feed-in terminal and a second ground terminal, and on said second sidewall is provided with a second resonance radiator, and said second resonance radiator is connected vertically to said second signal feed-in terminal, so as to form a non-coplanar structure, one end of said second ground terminal is extended and connected to said first ground terminal of said first antenna.

9. The built-in type antenna displayer as claimed in claim 8, wherein a third open slot is provided between said second signal feed-in terminal and said second ground terminal, and a fourth open slot is provided between said second signal feed-in terminal and said second resonance radiator.

10. The built-in type antenna displayer as claimed in claim 7, further comprising: aplastic cover plate and aplastic surface frame, said plastic cover plate is installed on a backside of said display panel, and a lock-and-fix piece is used to lock and fix said first metal bracket and said second metal bracket onto said plastic cover plate, so that said plastic surface frame is installed correspondingly on said plastic cover plate, and covers only said first metal bracket, said second metal bracket, and said metal frame, so as to expose a display screen of said display panel.
